(19) United States
(12) Patent Application Publication
(10) Pub. No.: US 2023/0055612 A1
(43) Pub. Date: Feb. 23, 2023

(54) CONNECTED SUBSTRATE AND METHOD FOR MANUFACTURING ELEMENT SUBSTRATE USING SAME

(71) Applicant: Nippon Electric Glass Co., Ltd., Shiga (JP)

(72) Inventor: Takahisa YAMAGUCHI, Shiga (JP)

(21) Appl. No.: 17/792,314

(22) PCT Filed: Feb. 19, 2021
(86) PCT No.: PCT/JP2021/006385

§ 371 Date: Jul. 12, 2022

(30) Foreign Application Priority Data
Mar. 6, 2020 (JP) 2020-038349

(51) Int. Cl. H01L 33/48; H01L 25/075; C03C 10/00

(52) U.S. Cl. CPC H01L 33/486; H01L 25/0753; C03C 10/0054; C03C 2214/20

(57) ABSTRACT

A connected substrate of the present invention includes a plurality of element substrate regions partitioned by dividing grooves, wherein the connected substrate is a glass ceramic sintered body having precipitated therein an anorthite crystal.

### TECHNICAL FIELD

The present invention relates to a connected substrate and a method of manufacturing an element substrate using the same. More specifically, the present invention relates to a connected substrate in which a plurality of element substrate regions for mounting, for example, a light emitting element such as a light emitting diode, each serving as one constituent unit, are connected to form an array, and to a method of manufacturing an element substrate including dividing the connected substrate to produce element substrates.

### BACKGROUND ART

Alight emitting device in which a light emitting element is mounted to an element substrate has hitherto been widely used. An LED, which is an example of the light emitting device, is a small and low power consumption light source. Of such LEDs, a white LED has been widely used as an alternative lighting device to an incandescent lamp or a fluorescent lamp.

Incidentally, there is an increasing demand for downsizing of such light emitting device, and there is a demand for downsizing of the substrate size of the element substrate. When the element substrate is to be downsized, in order to reduce a manufacturing cost, a connected substrate including a plurality of element substrate regions partitioned by vertical and horizontal dividing grooves is used, and the connected substrate after having been subjected to plating treatment or implementation of light emitting elements is divided into individual pieces in some cases. When the connected substrate is divided along the dividing grooves, a plurality of element substrates can be produced efficiently.

### CITATION LIST

Patent Literature 1: JP 5915527 B2

### SUMMARY OF INVENTION

### Technical Problem

In Patent Literature 1, there is a disclosure that division accuracy of a connected substrate is increased by reducing the surface roughness of an upper surface of the connected substrate to reduce burr and chipping.

However, the connected substrate described in Patent Literature 1 has a problem in that wet blasting treatment is required, resulting in a rise in manufacturing cost. Moreover, the inventor of the present invention has made a reproductive experiment of Patent Literature 1, and as a result, has found that burr and chipping are observed in element substrates after division, and the connected substrate still has a problem with its division accuracy.

The present invention has been made in order to solve the above-mentioned problems, and an object of the present invention is to provide a connected substrate excellent in division accuracy.

### Solution to Problem

The inventor of the present invention has found that, when a glass ceramic sintered body having precipitated therein an anorthite crystal is used as a connected substrate, the occurrence of burr and chipping can be suppressed in each of element substrates after division. Thus, the finding is proposed as the present invention. That is, according to one embodiment of the present invention, there is provided a connected substrate, comprising a plurality of element substrate regions partitioned by dividing grooves, wherein the connected substrate is a glass ceramic sintered body having precipitated therein an anorthite crystal.

The connected substrate according to the one embodiment of the present invention is the glass ceramic sintered body having precipitated therein an anorthite crystal. With this configuration, a glass component is less liable to flow into the dividing grooves at the time of sintering of a green sheet molded body or the like, with the result that the shapes of the dividing grooves are retained. As a result, burr and chipping are less liable to occur in element substrates after division.

In addition, in the connected substrate according to the one embodiment of the present invention, it is preferred that a ratio of an integrated intensity of a first strong line of the anorthite crystal to an integrated intensity of a first strong line of an alumina crystal in an X-ray diffraction pattern be 0.20 or more. The “ratio of an integrated intensity of a first strong line of the anorthite crystal to an integrated intensity of a first strong line of an alumina crystal in an X-ray diffraction pattern” may be calculated from an X-ray diffraction pattern measured for a powdery-destroyed or non-destructive sample of the connected substrate with an X-ray diffractometer.

In addition, in the connected substrate according to the one embodiment of the present invention, it is preferred that the glass ceramic sintered body be a glass ceramic sintered body containing glass and alumina powder, and a content of the alumina powder be from 45 mass, to 70 mass %.

In addition, in the connected substrate according to the one embodiment of the present invention, it is preferred that the alumina powder have an average particle diameter of from 0.5 μm to 3.0 μm.

In addition, in the connected substrate according to the one embodiment of the present invention, it is preferred that the glass be borosilicate glass.

In addition, in the connected substrate according to the one embodiment of the present invention, it is preferred that the glass comprise as a glass composition, in terms of mass %, 60% to 80% of SiO₂, 10% to 30% of B₂O₃, 1% to 5% of Li₂O+Na₂O+K₂O, and 0% to 20% of MgO+CaO+SrO+BaO. Herein, the “Li₂O+Na₂O+K₂O” means the total content of Li₂O, Na₂O, and K₂O. The “MgO+CaO+SrO+BaO” means the total content of MgO, CaG, SrO, and BaO.

A method of manufacturing an element substrate according to one embodiment of the present invention preferably comprises: a connected substrate preparation step of preparing the connected substrate; and a division step of dividing the connected substrate along dividing grooves to obtain element substrates.

A method of manufacturing a light emitting device according to one embodiment of the present invention preferably comprises: an element substrate preparation step of preparing the element substrate; and a device production step of mounting a light emitting element to the element substrate to produce a light emitting device.

### BRIEF DESCRIPTION OF DRAWINGS

FIG. 1 is a plan view for illustrating an example of an embodiment of a connected substrate of the present invention.

FIG. 2 is a sectional view of the connected substrate of FIG. 1 taken along the line A-A.

### DESCRIPTION OF EMBODIMENTS

Now, an example of a preferred embodiment of the present invention is described. However, the following embodiment is merely illustrative. The present invention is by no means limited to the following embodiment.

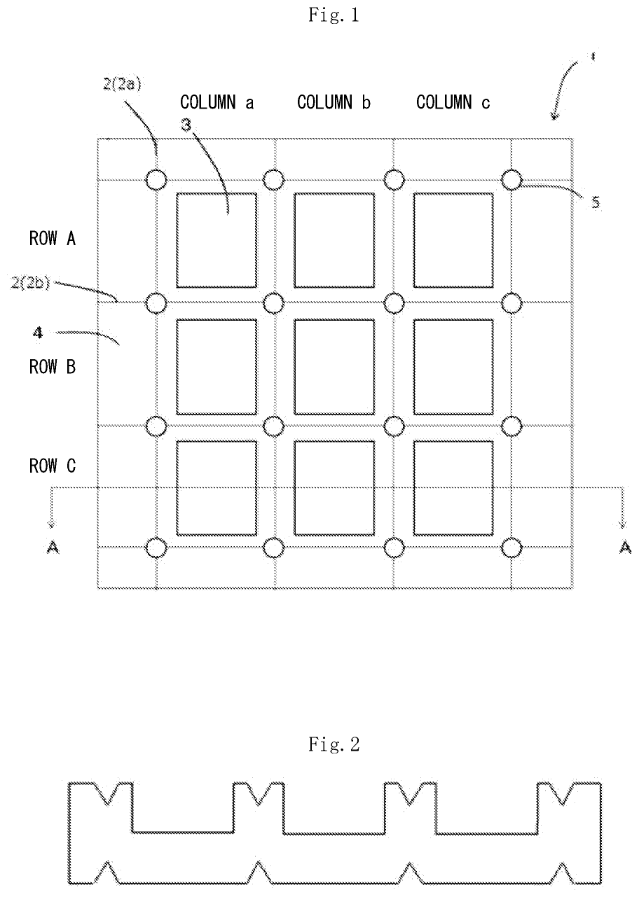

FIG. 1 is a plan view for illustrating an example of an embodiment of a connected substrate according to this embodiment. FIG. 2 is a sectional view of the connected substrate of FIG. 1 taken along the line A-A.

In FIG. 1, a connected substrate 1 comprises a plurality of element substrate regions 3 partitioned by dividing grooves 2. When the connected substrate 1 is divided along the dividing grooves 2, a plurality of element substrates can be produced efficiently.

In a center portion of the connected substrate 1 in a flat sheet shape, a total of nine element substrate regions 3 each serving as a constituent unit are arrayed next to each other in three columns (column “a”, column “b”, and column “c”) and three rows (row A, row B, and row C). Redundant portions 4 are present outside the nine element substrate regions 3 so as to surround these element substrate regions 3. The dividing grooves 2 comprising vertical dividing grooves 2a and horizontal dividing grooves 2b are formed on an upper surface of the connected substrate 1 at boundaries between the adjacent element substrate regions 3 out of the nine constituent units and at boundaries between the redundant portions 4 and the element substrate regions 3 of the connected substrate 1.

In addition, as illustrated in FIG. 2, the dividing grooves 2 are also formed on a lower surface opposite to the upper surface at positions corresponding to the dividing grooves on the upper surface. The connected substrate 1 is finally divided into nine element substrates independent of each other by, for example, applying stress to the dividing grooves. In addition, in order to prevent a situation in which a defect, such as burr or chipping, occurs in each of the element substrates at the time of division, a total of 16 dividing holes 5 each of which penetrates through the connected substrate 1 from the upper surface to the lower surface are formed so as to cut four corners of each of the element substrate regions 3.

The widths of opening portions of the dividing grooves 2 on the upper and lower surfaces of the connected substrate 1 are each preferably 1 μm or more. When the widths of the opening portions are each less than 1 μm, the division accuracy of the connected substrate 1 is reduced, with the result that burr and chipping are liable to occur in each of the element substrates after division.

The depths of the dividing grooves 2 are each preferably from 100 μm to 400 μm. When the depths of the dividing grooves 2 are each less than 100 μm, the division accuracy is liable to be reduced. Meanwhile, when the depths of the dividing grooves 2 are each more than 400 μm, the moldability of the connected substrate 1 is reduced. The depths of the dividing grooves 2 are each more preferably from 200 μm to 300 μm.

As illustrated in FIG. 2, the sectional shapes of the dividing grooves 2 are each preferably a triangle shape, but are not necessarily limited thereto and may be a rectangular shape or a U-shape.

The dividing grooves 2 are formed on both main surfaces of the connected substrate 1, but are not necessarily formed on both the main surfaces and may be formed only on the upper surface or the lower surface.

The connected substrate 1 is a glass ceramic sintered body having precipitated therein an anorthite crystal, and is preferably a sintered body of composite powder containing glass powder and alumina powder. With this configuration, the anorthite crystal is easily precipitated.

The glass powder is preferably borosilicate glass. The use of the borosilicate glass enables an increase in mechanical strength of the connected substrate 1.

The borosilicate glass preferably comprises as a glass composition, in terms of mass %, 60% to 80% of SiO₁, 10% to 30% of B₂O₃, 1% to 5% of Li₂O+Na₂O+K₂O, and 0% to 20% of MgO+CaO+SrO+BaO. In the following description of the content range of each component, the expression “%” means “mass %”, unless otherwise specified.

SiO₂ is a component that forms a glass skeleton. The content of SiO₂ is preferably from 60% to 80%. When the content of SiO₂ is small, vitrification may be difficult. Meanwhile, when the content of SiO₂ is large, a melting temperature is increased, and melting may become difficult. A more preferred range of the content of SiO₂ is from 65% to 75%.

B₂O₃ is a component that forms the glass skeleton, and widens a vitrification range to stabilize the glass. The content of B₂O₃ is preferably from 10% to 30%. When the content of B₂O₃ is small, there is a tendency that the melting temperature is increased, and the melting becomes difficult. Meanwhile, when the content of B₂O₃ is large, there is a tendency that the thermal expansion coefficient of the sintered body is increased. A more preferred range of the content of B₂O₃ is from 15% to 25%.

Alkali metal oxides (Li₂O, Na₂O, and K₂O) are each a component that reduces the melting temperature. The content (total content) of the alkali metal oxides is preferably from 1% to 5%. When the content of the alkali metal oxides is small, it becomes difficult to exhibit an effect of reducing the viscosity of the glass. Meanwhile, when the content of the alkali metal oxides is large, there is a tendency that water resistance is reduced. A more preferred range of the content of the alkali metal oxides is from 2% to 4%. The content range of each component of Li₂O, Na₂O, and K₂O is preferably from 0% to 4%, more preferably from 1% to 3%.

Alkaline earth metal oxides (MgO, CaO, SrO, and BaO) are each a component that reduces the melting temperature. The content (total content) of the alkaline earth metal oxides is preferably from 0% to 20%. When the content of the alkaline earth metal oxides is large, there is a tendency that the glass is liable to be unstable, and the glass is liable to be devitrified at the time of melting of the glass. A more preferred range of the content of the alkaline earth metal oxides is from 5% to 15%. The content range of each component of MgO, CaO, SrO, and BaO is preferably from 0% to 10%, more preferably from 1% to 8%.

Any other component than the above-mentioned components may be introduced into the glass composition as long as the effect of the present invention is not impaired.

The glass powder is preferably formed of glass having a glass transition point of 550° C. or more and 700° C. or less. When the glass transition point is less than 550° C., there is a risk in that degreasing of a green sheet may become difficult. When the glass transition point is more than 700° C., there is a risk in that dimensional accuracy may be reduced owing to an increase in shrinkage start temperature.

The glass powder is preferably formed of glass in which an anorthite crystal is precipitated through firing at 800° C. or more and 930° C. or less. When no anorthite crystal is precipitated, there is a risk in that sufficient mechanical strength cannot be obtained. Further, the glass powder preferably has a crystallization peak temperature of 80° C. or less measured by differential thermal analysis (DTA). When the crystallization peak temperature is more than 880° C., there is a risk in that the dimensional accuracy of the sintered body may be reduced.

The glass powder may be produced by blending glass raw materials so as to obtain glass having the above-mentioned glass composition, melting the grass raw materials to obtain molten glass, and then forming the obtained molten glass into a film shape or the like, followed by pulverization by a dry pulverization method or a wet pulverization method. In the case of the wet pulverization method, water or ethyl alcohol is preferably used as a solvent. As a pulverizer, there are given, for example, a roll mill, a ball mill, and a jet mill.

The glass powder preferably has an average particle diameter D₅₀ of from 0.5 μm to 3 μm. When the average particle diameter D₅₀ of the glass powder is less than 0.5 μm, the glass powder is liable to be aggregated, and not only its handling but also its uniform dispersion becomes difficult. Meanwhile, when the average particle diameter D₅₀ of the glass powder is more than 3 μm, there is a risk in that the softening temperature of the glass powder may be increased, or insufficient sintering may occur. The “average particle diameter D₅₀” refers to a value measured by laser diffractometry, and represents, in a cumulative particle size distribution curve on a volume basis measured by the laser diffractometry, a particle diameter at which the integration amount of particles from a smaller particle side is 50% in a cumulative manner.

In the connected substrate 1, it is preferred that the ratio of the integrated intensity of the first strong line of an anorthite crystal to the integrated intensity of the first strong line of an alumina crystal in an X-ray diffraction pattern be 0.20 or more. When the ratio is less than 0.20, a glass component of the glass ceramic sintered body buries the dividing grooves 2 at the time of sintering of a green sheet molded body, and hence burr and chipping are liable to occur in each of the element substrates, with the result that the division accuracy of the connected substrate 1 is liable to be reduced.

The content of the alumina powder in the glass ceramic sintered body is preferably from 45 mass % to 70 mass %, more preferably from 45 mass % to 58 mass %, still more preferably from 50 mass % to 57 mass %. When the content of the alumina powder is small, the strength of glass ceramics itself is reduced. Meanwhile, when the content of the alumina powder is large, sinterability is reduced, and the strength of the sintered body is reduced.

The alumina powder has an average particle diameter D₅₀ of preferably from 0.5 μm to 3.0 μm, more preferably from 1.0 μm to 2.0 μm. When the average particle diameter D₅₀ of the alumina powder is too small, the alumina powder diffuses into the glass, and it becomes difficult to precipitate the anorthite crystal. Meanwhile, when the average particle diameter D₅₀ of the alumina powder is large, a reaction between the glass and the alumina powder is excessively suppressed, and it becomes difficult to precipitate the anorthite crystal.

Next, a method of manufacturing the connected substrate 1 is described.

(A) Production of Green Sheet

First, composite powder containing the glass powder and the alumina powder is produced, and a binder and, as required, a plasticizer, a dispersant, a solvent, and the like are added to the composite powder to prepare a slurry. Next, the obtained slurry is formed into a sheet shape by a doctor blade method or the like, dried, and then processed into a predetermined shape. Thus, a green sheet is obtained.

As the binder, for example, polyvinyl butyral and an acrylic resin are suitable. As the plasticizer, for example, dibutyl phthalate, dioctyl phthalate, and butyl benzyl phthalate are suitable. As the solvent, organic solvents, such as methyl ethyl ketone, toluene, xylene, 2-propanol, and 2-butanol, are suitable.

(B) Formation of Conductor Paste Layer

A conductor paste layer for forming a wiring conductor layer, an external electrode terminal, a connection via, a thermal via, a heat dissipation layer, or the like is formed on the surface of and inside the green sheet. For example, metal powder containing, as a main component, copper, silver, gold, platinum, palladium, or the like that is made into a paste form through addition of a vehicle such as ethyl cellulose, and as required, a solvent and the like may be used as a conductor paste.

(C) Production of Green Sheet Molded Body

The green sheets each having formed thereon and therein the conductor paste layer are laminated on each other in a predetermined order, and a green sheet for a frame body is further laminated on the uppermost green sheet. After that, the green sheets are integrated with each other by thermocompression bonding. Thus, a green sheet molded body is obtained.

(D) Formation of Dividing Groove 2 and Dividing Hole 5

On both main surfaces of the green sheet molded body, the dividing grooves 2 are formed in the form of four vertical lines and four horizontal lines at boundaries between the element substrate regions 3 arrayed in three columns and three rows with a cutting machine for a laminated ceramic green sheet or the like. Further, with regard to 16 intersection points between the dividing grooves 2, the dividing holes 5 each of which has a circular shape and penetrates through the green sheet molded body in a thickness direction are formed around the intersection points with a hole forming machine or the like. As required, the dividing holes 5 may be formed in each of the green sheets.

(E) Firing of Green Sheet Molded Body

After having been subjected to degreasing of the binder and the like as required, the green sheet molded body having formed therein the dividing grooves 2 and the dividing holes 5 is subjected to firing for sintering the green sheet molded body. Thus, the connected substrate 1 is obtained.

For example, the degreasing is preferably performed under the conditions that the green sheet molded body is retained at a temperature of 500° C. or more and 600° C. or less for 1 hour or more and 10 hours or less. When the degreasing temperature is less than 500° C. or the degreasing time is less than 1 hour, there is a risk in that the binder and the like cannot be removed sufficiently. Meanwhile, when the degreasing temperature is set to about 600° C. and the degreasing time is set to about 10 hours, the binder and the like can be removed sufficiently. When the degreasing temperature is more than 600° C. or the degreasing time is more than 10 hours, there is a risk in that the production efficiency of a connected substrate 1 may be reduced.

In consideration of the denseness, division accuracy, productivity, and the like of the connected substrate 1, the firing of the green sheet molded body is preferably performed so that the green sheet molded body is retained at a temperature of 850° C. or more and 900° C. or less for 20 minutes or more and 60 minutes or less, and is particularly preferably performed at a temperature of 860° C. or more and 880° C. or less. When the firing temperature is less than 850° C., the denseness of the connected substrate 1 is liable to be reduced. Meanwhile, when the firing temperature is more than 930° C., there is a risk in that the structure of the connected substrate 1 may be excessively densified, the surface roughness of groove internal surfaces of the dividing grooves 2 may be excessively reduced, and the division accuracy of the connected substrate 1 may be reduced. In addition, there is also a risk in that the connected substrate 1 may be deformed, and the production efficiency may be reduced. In addition, in the case of using a conductor paste containing silver powder, when the firing temperature is more than 880° C., there is also a risk in that the conductor paste layer may excessively soften, and a predetermined shape cannot be maintained.

While the method of manufacturing the connected substrate 1 has been described above, the green sheet for a frame body is not necessarily a single green sheet and may be a laminate of a plurality of green sheets. Further, the order of the steps or the like may be appropriately changed as long as the connected substrate 1 can be manufactured.

A method of manufacturing an element substrate of the present invention preferably comprises: a connected substrate preparation step of preparing the connected substrate; and a division step of dividing the connected substrate along dividing grooves to obtain element substrates. With this configuration, the manufacturing efficiency of the element substrate can be significantly increased.

A method of manufacturing a light emitting device of the present invention preferably comprises: an element substrate preparation step of preparing the element substrate; and a device production step of mounting a light emitting element to the element substrate to produce a light emitting device. With this configuration, the manufacturing efficiency of the light emitting device can be significantly increased.

### EXAMPLES

Next, specific Examples of the present invention are described. The present invention is not limited to these Examples.

Examples (Sample Nos. 1 to 6) of the present invention and Comparative Example (Sample No. 7) are shown in Table 1.

TABLE 1

| | No. 1 | No. 2 | No. 3 | No. 4 | No. 5 | No. 6 | No. 7 |
|---|---|---|---|---|---|---|---|
| G1ass powder | 50 | 45 | 43 | 50 | 45 | 43 | 65 |
| (mass %) | | | | | | | |
| Glass powder | 2.7 | 2.7 | 2.7 | 2.7 | 2.7 | 2.7 | 2.7 |
| D₅₀ (μm) | | | | | | | |
| Alumina | 50 | 55 | 57 | 50 | 55 | 57 | 35 |
| powder | | | | | | | |
| (mass %) | | | | | | | |
| Alumina | 1.9 | 1.9 | 1.9 | 1.1 | 1.2 | 2.4 | 1.1 |
| powder D₅₀ | | | | | | | |
| (μm) | | | | | | | |
| Ratio in | 0.6 | 0.6 | 0.7 | 0.3 | 0.3 | 0.8 | 0 |
| integrated | | | | | | | |
| intensity of | | | | | | | |
| first strong | | | | | | | |
| line between | | | | | | | |
| anorthite/al | | | | | | | |
| umina in XRD | | | | | | | |
| pattern | | | | | | | |
| Dividing | ◯ | ◯ | ◯ | Δ | Δ | ◯ | X |
| proterty | | | | | | | |

Various glass raw materials were blended so as to give borosilicate glass comprising, as a glass composition, 70 mass % of SiO₂, 28 mass % of B₂O₃, and 2 mass % of K₂O, and were then loaded into a platinum crucible and melted at 1,600° C. to obtain molten glass. The obtained molten glass was down-drawn by being supplied between two water-cooled rotating rolls to obtain glass in a film shape. The glass film thus obtained was pulverized and classified. Thus, glass powder having an average particle diameter D₅₀ shown in Table 1 was obtained.

Composite powder was obtained by mixing the glass powder and alumina powder having an average particle diameter D₅₀ shown in Table 1 at a ratio shown in Table 1. 12 Parts by mass of an acrylic resin, 3 parts by mass of a plasticizer, and 35 parts by mass of a solvent were then mixed and kneaded with 100 parts by mass of the composite powder. Thus, a slurry was obtained.

The obtained slurry was applied onto a PET film by a doctor blade method and dried to obtain a green sheet. The green sheets were then laminated on each other to obtain a green sheet molded body that had a flat sheet shape and measured 190 mm by 190 mm in size and 0.1 mm in thickness after sintering. The green sheet molded body was obtained by laminating the green sheets on each other in an appropriate order after subjecting each of the green sheets to formation of dividing holes, filling and printing of a conductor paste, and the like as required.

Next, dividing grooves each having a depth of 200 μm were formed in the form of four vertical lines and four horizontal lines on both the front and rear surfaces of the green sheet molded body with a cutting machine for a laminated ceramic green sheet to obtain an unburnt connected substrate. The unburnt connected substrate was degreased by being retained at 500° C. for 5 hours, and was then fired by being retained at 870° C. for 60 minutes. Thus, a connected substrate was produced.

The ratio of the integrated intensity of the first strong line of an anorthite crystal to the integrated intensity of the first strong line of an alumina crystal in an X-ray diffraction (XRD) pattern may be calculated from an X-ray diffraction pattern measured for a powdery-destroyed or non-destructive sample of the connected substrate with an X-ray diffractometer.

Next, the connected substrate was divided along the dividing grooves to obtain element substrates. A dividing property was evaluated by measuring the number of burrs and chippings occurring on the surface of the obtained element substrate. Specifically, the evaluation was performed as follows: the surface of the element substrate was observed with an optical microscope; and a case in which the occurrence of burr and chipping in a size of 50 μm or more was not observed was represented by Symbol “∘”, a case in which the occurrence of burr and chipping in a size of 100 μm or more was not observed, but the occurrence of burr and chipping in a size of 50 μm or more and less than 100 μm was observed was represented by Symbol “Δ”, and a case in which the occurrence of burr and chipping in a size of 100 μm or more was observed was represented by Symbol “x”. The evaluation results are shown in Table 1.

As apparent from Table 1, each of Sample Nos. 1 to 6, in which an anorthite crystal was precipitated in the connected substrate, had a satisfactory dividing property. Meanwhile, Sample No. 7, in which no anorthite crystal was precipitated in the connected substrate, had a poor dividing property.

### INDUSTRIAL APPLICABILITY

A light emitting device utilizing the element substrate according to the present invention is suitable as a backlight of a cellular phone, a liquid crystal TV, a liquid crystal display, or the like, an automobile or decorative lighting device, and any other light source.

### REFERENCE SIGNS LIST

1 connected substrate, 2 dividing groove, 3 element substrate region, 4 redundant portion, 5 dividing hole

1. A connected substrate, comprising a plurality of element substrate regions partitioned by dividing grooves,
wherein the connected substrate is a glass ceramic sintered body having precipitated therein an anorthite crystal.

2. The connected substrate according to claim 1, wherein a ratio of an integrated intensity of a first strong line of the anorthite crystal to an integrated intensity of a first strong line of an alumina crystal in an X-ray diffraction pattern is 0.20 or more.

3. The connected substrate according to claim 1,
wherein the glass ceramic sintered body is a glass ceramic sintered body containing glass and alumina powder, and
wherein a content of the alumina powder is from 45 mass % to 70 mass %.

4. The connected substrate according to claim 3, wherein the alumina powder has an average particle diameter of from 0.5 μm to 3.0 μm.

5. The connected substrate according to claim 3, wherein the glass is borosilicate glass.

6. The connected substrate according to claim 3, wherein the glass comprises as a glass composition, in terms of mass %, 60% to 80% of SiO₂, 10% to 30% of B₂O₃, 1% to 5% of Li₂O+Na₂O+K₂O, and 0% to 20% of MgO+CaO+SrO+BaO.

7. A method of manufacturing an element substrate, comprising:
a connected substrate preparation step of preparing the connected substrate of claim 1; and
a division step of dividing the connected substrate along dividing grooves to obtain element substrates.

8. A method of manufacturing a light emitting device, comprising:
an element substrate preparation step of preparing the element substrate of claim 7; and
a device production step of mounting a light emitting element to the element substrate to produce a light emitting device.
